(19) United States
(12) Patent Application Publication
(10) Pub. No.: US 2017/0347487 A1
(43) Pub. Date: Nov. 30, 2017

(54) Reverse flow microstructure water cooling unit with included pump for cooling of an electrical or electronic component

(71) Applicants: Andreas Rudnicki, Braunschweig (DE); Nathanael Draht, Schloss Holte (DE)

(72) Inventors: Andreas Rudnicki, Braunschweig (DE); Nathanael Draht, Schloss Holte (DE)

(21) Appl. No.: 15/163,861

(22) Filed: May 25, 2016

(51) Int. Cl. H05K 7/20; F28F 13/12; F28F 3/02

(52) U.S. Cl. CPC H05K 7/20272; H05K 7/20263; F28F 3/022; F28F 13/12

(57) ABSTRACT

Reverse flow microstructure water cooling unit for cooling of an electrical or electronic component which already includes an electrical pump which is placed above the middle of the bottom plate sucking the water out of the bottom micro fin cross structure and thereby generates micro turbulences which improve the cooling capability of the whole water cooling unit.

### FIELD OF THE INVENTION

This invention relates to a cooler for electrical or electronic components, in detail to fluid coolers for PC components like processors, graphics chips, memory units, voltage converters, hard drives and other electrical or electronic components, that dissipate heat, that are known for example from the patent DE102008058032.5 US6, 105.373 U.S. Pat. No. 8,240,362B2 U.S. Pat. No. 8,245,746B2 and DE102004018144B4

### DESCRIPTION OF THE RELATED ART OF TECHNIQUE

From DE102004018144B4 it is known, for example, that in modern computers, the electronic components of graphics cards and processors, the so-called CPUs, are inherently subject to high thermal loads which occur during their operation. Due to the ever-narrowing circuit structures and the increasing performance of these processors they heavily heat up during operation. To ensure a high and uniform computer power and to protect the processor from thermal damage, all of these were actively cooled. A conventional cooling air provides a cooler in form of a front fan that supplies the electronic device regulated or unregulated with cooling air. The heated air is discharged to the environment in general.

In high-performance computers this type of cooling has limitations. Particularly in large computer systems is the heating of the rooms where computers are set up a problem which is encountered with the use of air conditioners with high energy costs.

As an alternative to pure air cooling liquid cooler for electronic processors are available amplified, which comprise a bottom plate, usually made of copper, on which one on side the processor is arranged, while the other side is subjected to a stream of cooling water. This cooling water is, for example, provided through an injection plate with feed and discharge connections, with which the bottom plate is in contact.

Reference may be made here by way of example on coolers, which are known from U.S. Pat. No. 6,105,373, U.S. Pat. No. 5,239,443. Thus, the one described in U.S. Pat. No. 6,105,373 thermoelectric cooler has a bottom plate and a multi-piece nozzle plate, wherein at the first side of the bottom plate an electronic component that needs to be cooled can be mounted and opposite the injection plate can be attached. On the injection plate, a feed port and a discharge port for a liquid cooling medium are included. For the distribution of the cooling medium there is a chamber formed in the injection plate, which is connected to the feed port and to the outlet holes or ejection nozzles. The outlet openings of the ejection nozzles or discharge orifices are directed towards the electronic component facing away from the side of the bottom plate, so that it is actively cooled by the cooling medium. The discharge of the heated cooling medium from the cooling space is formed between the outside of the chamber and the electronic component facing away from the side of the base plate.

Although this liquid-cooled cooling device has significant advantages relative to air-cooled cooling devices for an electronic component, it can, as regards the cooling effect, be further improved. It should be referred to the microstructure cooler DE102008058032.5, which preferably allows a further increase due to the new etching technology through the production of very fine structures. The base plates that are manufactured from etching process require very thin (for example 1 mm) materials, so that they can be screwed only with expensive thread insert with the top. Therefore, current microstructure cooler again are manufactured by milling and possibly additionally provided with a top and an injection plate. The bottom of an so produced cooler is between 3 and 5 mm thick and usually must be processed very complicated to achieve inside a remaining thickness of preferably <0.5 mm and a fin height of 2 to 3 mm.

Microstructure coolers of the current state of the art are challenged to allow a sufficiently high flow and the greatest possible cooling capacity. To allow a large flow rate, the cooling channels must have a certain height in the soil, for example, 4 mm, and a corresponding width, for example 1 mm, so that the microstructure cooler is not a flow brake for the water circuit. In order to achieve the greatest possible cooling power, the cooling channels may be as thin as possible, for example <0.5 mm, and the height as low as possible, such as <2 mm, so that the coolant can absorb the heat directly from the heat transferor point. However, so designed coolers have a very high resistance to flow, so that thus constructed cooler with conventional pumps used in computer water cooling systems cannot be carried out effectively. The currently in such coolers used technique requires the water inlet to the middle of the bottom plate through an injection plate, and may even have water recirculation technology to increase the flow rate and the cooling performance.

Other models like shown in U.S. Pat. No. 8,240,362B2 have already included a pump in the water block. This pump has basically 2 ways to operate: 1) push the water through an injection plate into the middle of the bottom plate from where the water spreads to all directions or 2) push the water not centred on one side into the bottom plate, from where the water flows (from left to right for example, see U.S. Pat. No. 8,240,362B2) through the channel or fin structure of the bottom plate. Both this ways use state of the art technology and are limited by the same restrictions as if the pump was not included in the water block.

Against this background, the present invention seeks to increase the water flow and cooling performance by integrating the pump into the water block and thereby changing the water flow direction, so that the pump sucks the water out of the middle of the bottom plate. The solution to this problem results from the features of the main claim, while advantageous embodiments and further developments of the invention are noted in the dependent claims.

The invention is based on the discovery that the water flow in the bottom of a micro-structure cooler cannot be improved since any flow optimization in the form of an increase or enlargement of the cooling channels leads to an expense of cooling capacity. Also the micro channel technology known from patent DE102008058032.5 has been advanced and applied to the current manufacturing techniques for microstructure coolers, so that the cooling capacity of a bottom plate produced by conventional milling techniques with very fine and aligned parallel and flat cooling channels, is increased in both the flow and the cooling capacity by an injection plate with water recirculation channels, this invention goes a complete different way of performance increase.

The performance increase is based on a change of the water flow direction and turbulences from the pump. State of the art water coolers with injection plate and even with additional water recirculation channels only work if the water inlet is in the middle of the bottom plate. If you change the water flow in these water blocks, the cooling performance will decrease. But if the pump axis is positioned directly above the middle of the bottom plate, the rotation of the impeller will cause micro tornados which go down into the bottom plate micro pin cooling structure and there speed up the water flow which improves the heat absorption rate of the cooling medium.

From mass production perspective it is possible to use the same bottom plate as state of the art water blocks but use another middle plate, pump and top, so that for the same floor structure only by the reverse of the water flow and the micro-turbulences caused by the pump, the cooling capacity of existing models is increased.

For the development of new models, it is possible to change the bottom plate by using bigger channels in which the micro-turbulences of the pump will increase the water flow rate and cooling performance, so that a constant or increased cooling power and flow rate is achieved along with substantially reduced manufacturing costs for the base plate. The manufacturing costs of a base plate will be the lower, the bigger the channels are, since the cooling channels are usually produced by milling cutter discs and with increasing thickness the milling cutter disc can be build bigger and more stable and therefore be run with a higher speed by less damage/breaks.

The middle plate will have 1 or more soaking holes. Recirculation channels on the bottom side will no longer be needed. But for further flow optimization it is possible to add small parts of bended rubber rings on the bottom side of the middle plate that support the tornado effect from the pump impeller in the bottom plate micro structure and therefore increase the cooling performance.

Divergent from applying the pump soaking hole and rubber rings in the middle plate, it is also possible to include the technology directly in the top of a microstructure cooler.

Depending on the application and system conditions such as the parallel operation of several coolers (for example for multi-processor systems) or the cooling of other components such as graphics chips, hard drives, memory chips and other heat dissipating components, the pump power and rubber rings and the channel structure can be customized.

### SUMMARY

The invention concerns a reverse flow water cooling technology with included pump for microstructure water cooling units for an electrical or electronic component
which has a pump positioned directly above the middle of the base plate
which has a reverse water flow where the pump sucks the water out of the middle of the base plate
which allows a flow increase
which provides additional tornado turbulence in the base plate, leading to a local increase of the flow speed
which has attached rubber rings on the lower side of the middle plate, which increase the effect of the tornado turbulences from the pump
which improves the heat transfer from the base plate to the cooling medium
which improves the existing coolers in the cooling capacity and the flow rate
which enables bigger channels in the base plate at constant or increased cooling power and flow rate for new coolers
   with which a fluid operated cooler for electrical or electronic components can be improved in terms of the cooling capacity and the flow rate by installing a pump and running the water block at reverse water flow

### EMBODIMENT

An exemplary embodiment is described with reference to the accompanying figures. In the drawings:

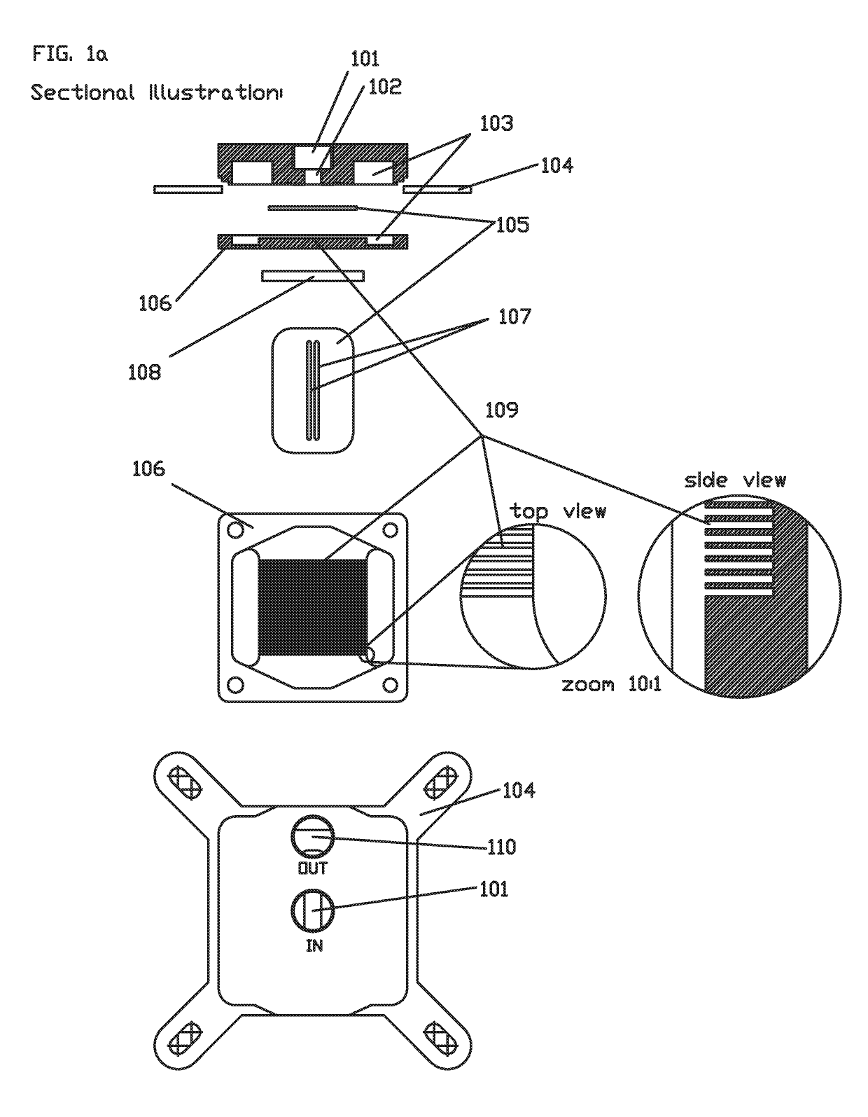

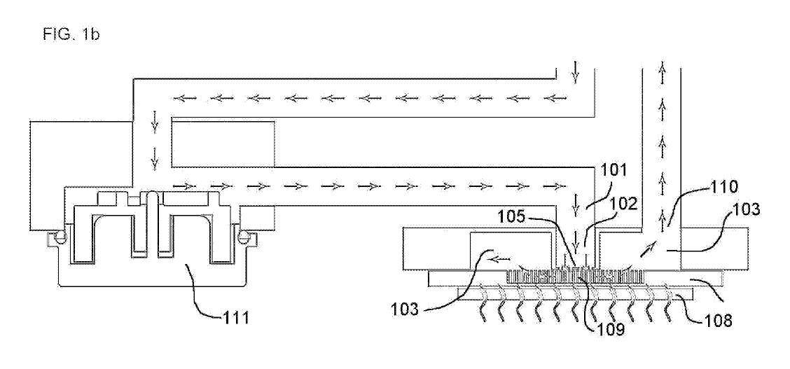

FIGS. 1a and 1b—Prior art. The CPU cooler pictured here shows the typical current CPU cooler art. The cooling medium is distributed through an inlet (101) into a prechamber (102), and from there through the injection plate (105) concentrically with one or two slits (107) of the fin structure/cooling channels (109) directed to the base plate (106) to escape from there through the cooling channels (109) outwardly and thereby absorb the heat from the heat source (108). The cooling medium is then collected in the backwater chamber (103) and discharged via outlet (110). The whole water block is mounted via the mounting plate (104). From there the water flows to the radiator and back to the pump (111).

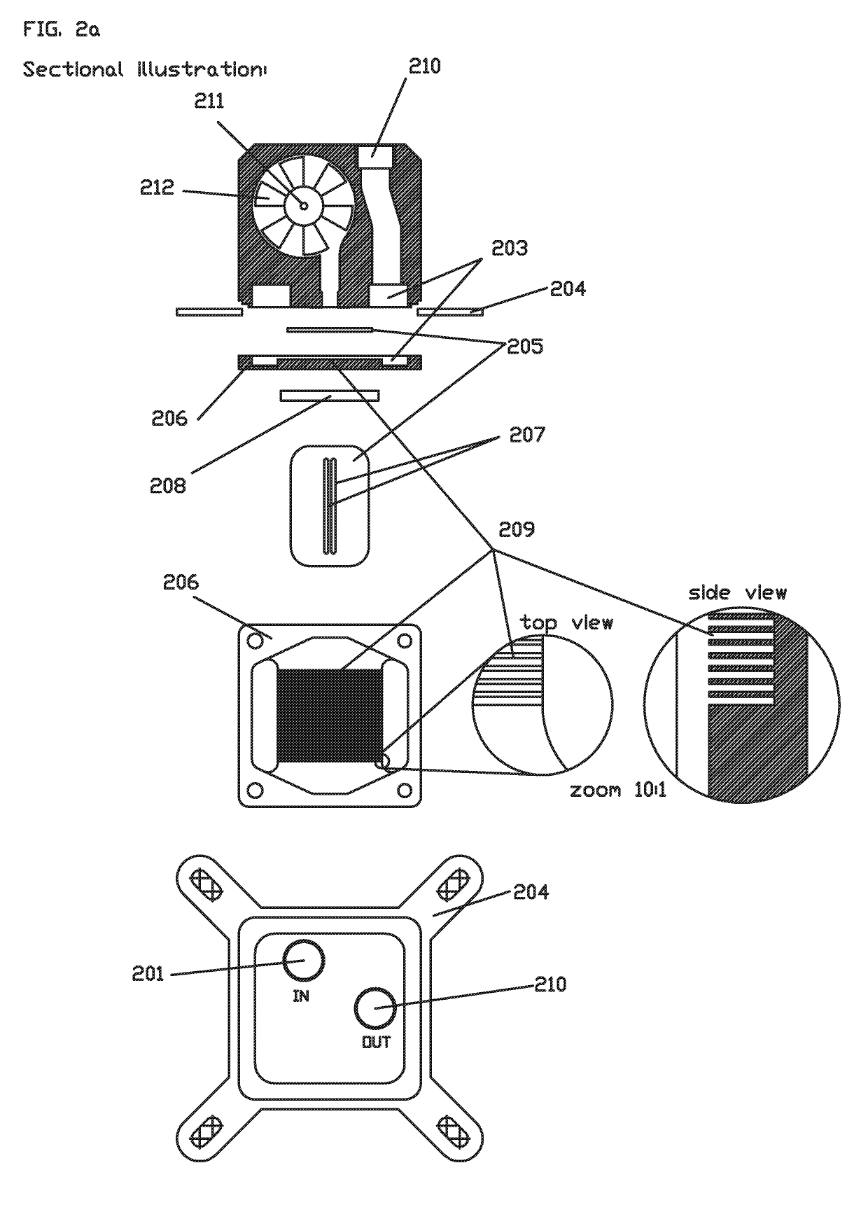

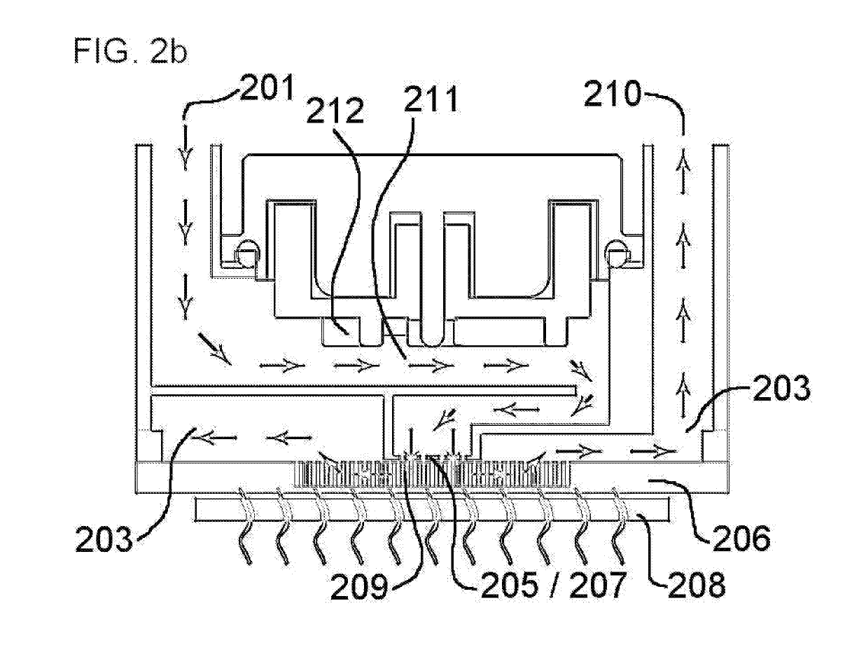

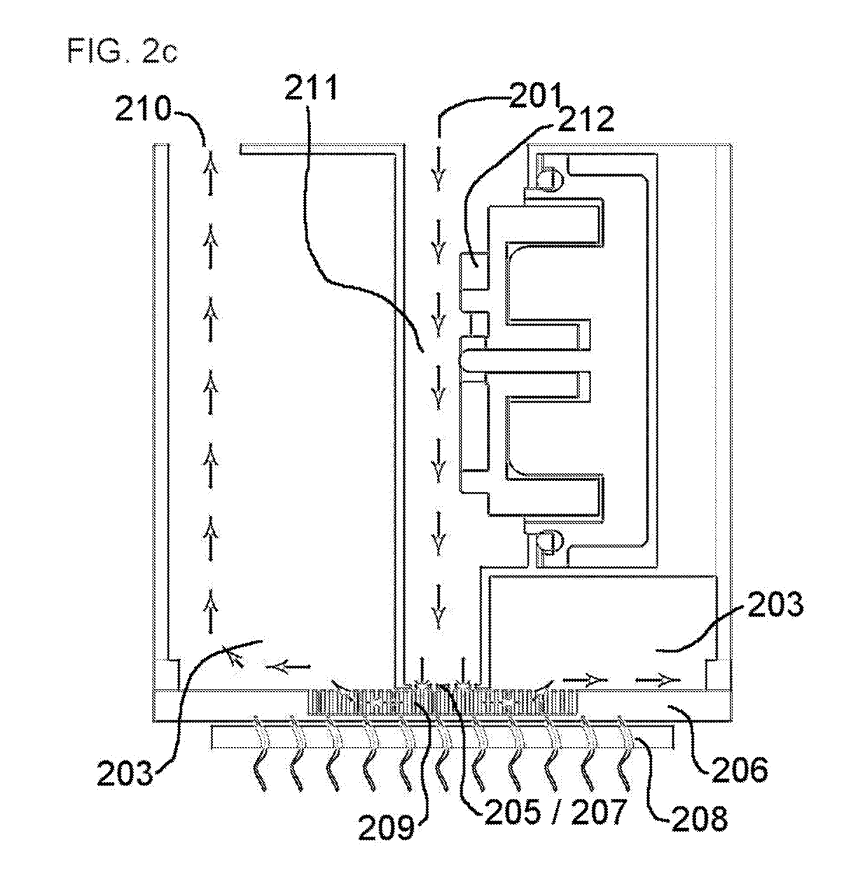

FIG. 2a, 2b and 2c—Prior art. The CPU cooler pictured here shows the typical current CPU cooler art with included pump. The cooling medium is distributed through an inlet (201) into the middle of the pump (211) where it is accelerated by the impeller (212) and from there downwards through the injection plate (205) concentrically with one or two slits (207) of the fin structure/cooling channels (209) directed to the base plate (206) to escape from there through the cooling channels (209) outwardly and thereby absorb the heat from the heat source (208). The cooling medium is then collected in the backwater chamber (203) and discharged via outlet (210). The whole water block with pump is mounted via the mounting plate (204).

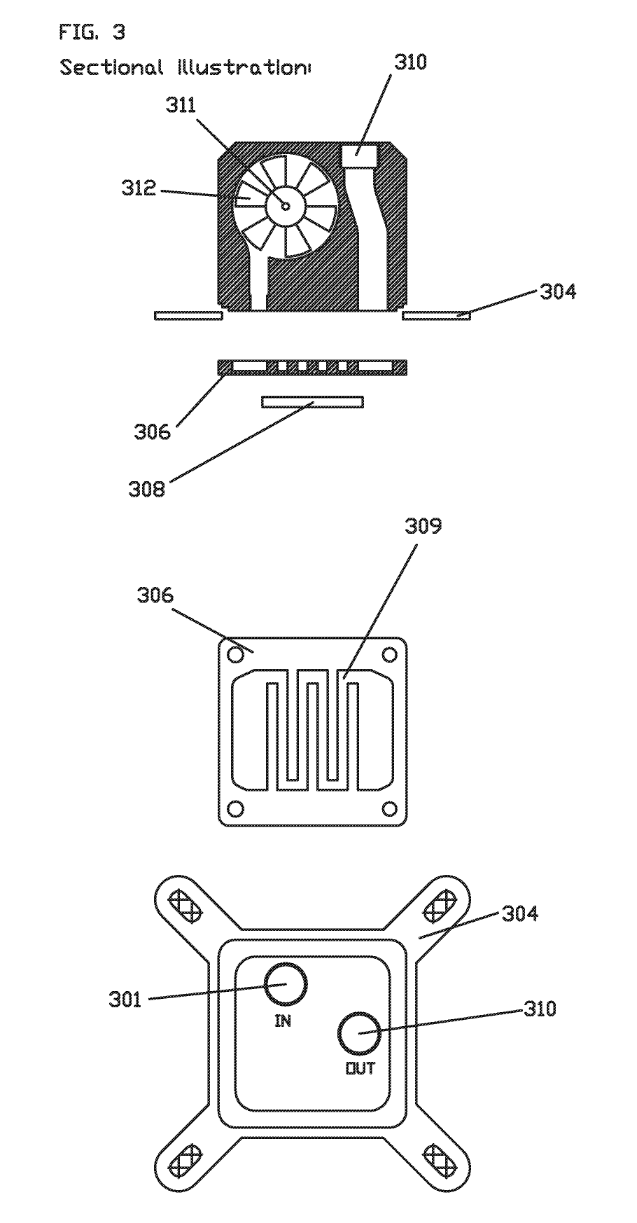

FIG. 3—Prior art. The CPU cooler pictured here shows the typical current CPU cooler art with included pump but without micro fin structure and without injection plate. The cooling medium is distributed through an inlet (301) into the middle of the pump (311) where it is accelerated by the impeller (312) and from there downwards to the left side of the bottom plate (306), then running through the cooling channels (309) from one side to another and thereby absorb the heat from the heat source (308). The cooling medium is then and discharged via outlet (310). The whole water block with pump is mounted via the mounting plate (304).

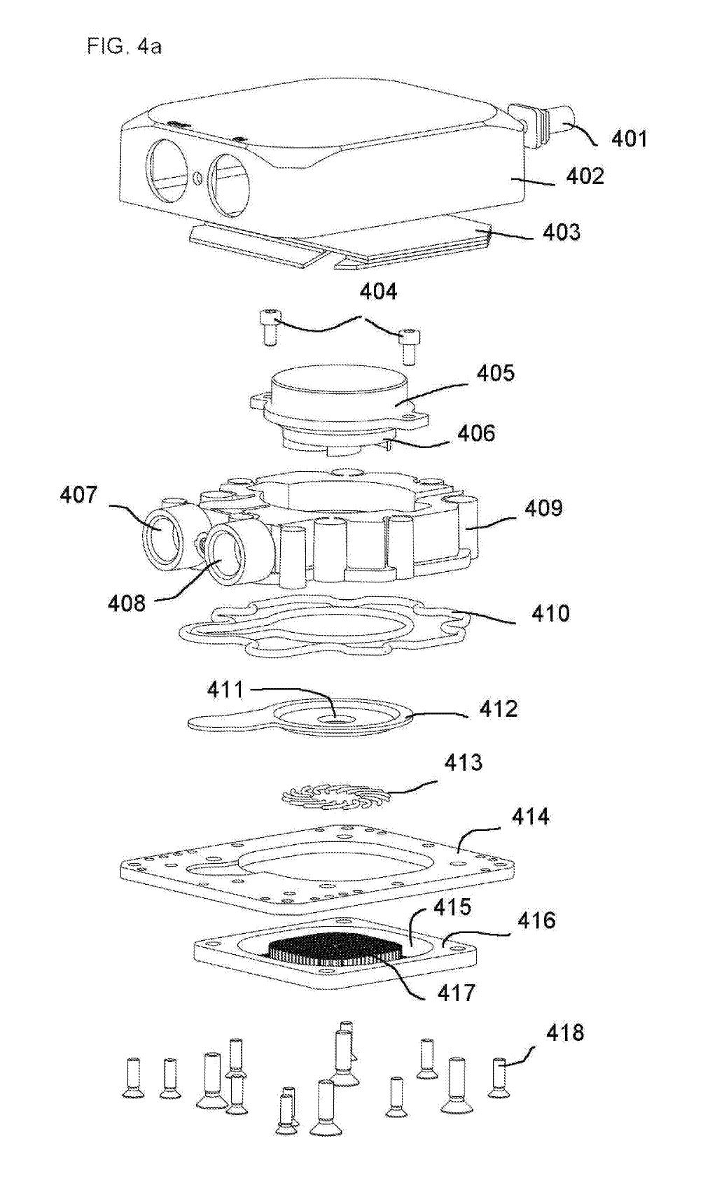

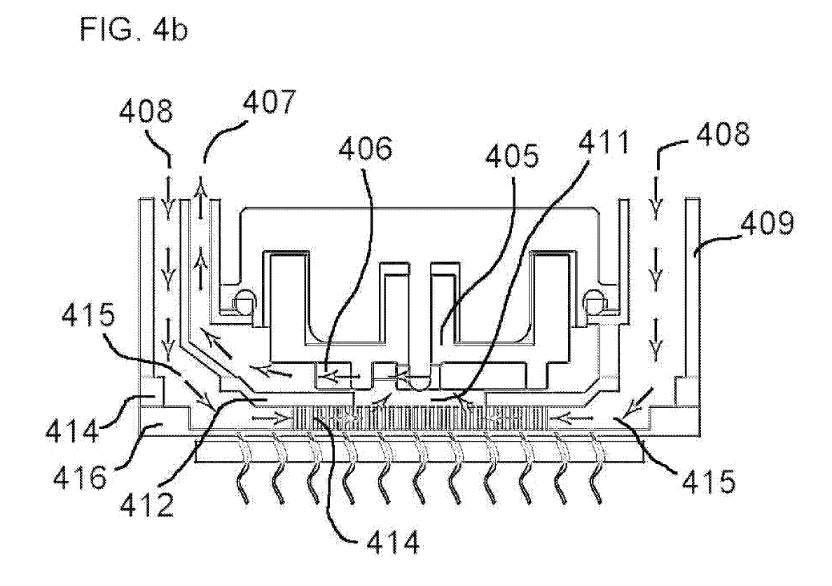

FIGS. 4a and 4b—New water block with reverse water flow and centred pump. The water enters the water block in the inlet (408) and is lead through the top (409) between the middle plate (412) and mounting plate (414) to enter the bottom plate (416) in the outside water chamber (415) and then go into the fin structure (414), from there it is soaked into the pump (405) through the pump inlet hole (411) with the impeller (406) creating micro tornado turbulences which are intensified by the tornado rubber rings (413) and then discharged via the outlet (407). Additionally there is a pump power cable outlet (401) in the top cover (402) that includes insulation material (403) screws to hold the pump (404) an O-ring (410) several mounting options in the mounting plate (414).

1. Reverse flow microstructure water cooling unit with included pump for cooling of an electrical or electronic component
With a bottom plate, a middle plate, a pump and a top,
In which the middle plate has one or more holes in the middle for the water outlet
In which the bottom plate has cross structure cooling pins,
In which the pump is positioned with the pump axis directly above of the water outlet holes of the middle plate
So that by the sucking of the water from the pump micro tornado turbulences in the cross structure of the bottom plate arise that increase the cooling capacity of the cross structure cooling pins in the bottom plate

2. Microstructure water cooling unit as described in claim 1, characterized in that additionally recirculation channels are implemented in the middle plate.

3. Microstructure water cooling unit as described in claim 1, characterized in that additionally tornado rubber rings are implemented in the middle plate.
